(19) United States
(12) Patent Application Publication
(10) Pub. No.: US 2025/0098379 A1
(43) Pub. Date: Mar. 20, 2025

(54) DISPLAY DEVICE AND MANUFACTURING METHOD THEREOF

(71) Applicant: Samsung Display Co., LTD., Yongin-si (KR)

(72) Inventors: Jinouk SONG, Yongin-si (KR); Ilhoo PARK, Yongin-si (KR); Jin Sook BANG, Yongin-si (KR); Sang Hoon YIM, Yongin-si (KR); Seong Jin JEONG, Yongin-si (KR)

(73) Assignee: Samsung Display Co., LTD., Yongin-si (KR)

(21) Appl. No.: 18/735,511

(22) Filed: Jun. 6, 2024

(30) Foreign Application Priority Data
Sep. 19, 2023 (KR) 10-2023-0124713

(51) Int. Cl. H01L 33/58

(52) U.S. Cl. CPC H10H 20/855

(57) ABSTRACT

A display device includes a substrate, a light emitting device disposed on the substrate, a first layer disposed on the light emitting device, a high refractive index layer disposed on the first layer and overlapping the light emitting device, and a low refractive index layer disposed on the first layer and having a lower refractive index than the high refractive index layer, wherein a side surface of the high refractive index layer and a side surface of the low refractive index layer are in contact with each other, and to form an inclined surface, and an angle of the inclined surface is in a range of about 45 to about 80 degrees.

### CROSS-REFERENCE TO RELATED APPLICATION(S)

This application claims priority to and benefits of Korean Patent Application No. 10-2023-0124713 under 35 U.S.C. § 119, filed on Sep. 19, 2023, in the Korean Intellectual Property Office, the entire contents of which are incorporated herein by reference.

### BACKGROUND

### 1. Field of the Invention

Embodiments relate to a display device and a method of manufacturing the display device.

### 2. Description of the Related Art

A light emitting device is a device that forms excitons by combining holes supplied from the anode and electrons supplied from the cathode within the light emitting layer formed between the anode and the cathode, and emits light as the excitons stabilize.

Light emitting devices have various advantages such as a wide viewing angle, a fast response speed, thinness, and low power consumption, so they are widely applied to various electrical and electronic devices such as televisions, monitors, and mobile phones.

### SUMMARY

Embodiments provide a display device capable of improving luminous efficiency and a method of manufacturing the display device.

However, embodiments are not limited to those set forth herein. The above and other embodiments will become more apparent to one of ordinary skill in the art to which the disclosure pertains by referencing the detailed description of the disclosure given below.

A display device according to an embodiment may include a substrate, a light emitting device disposed on the substrate, a first layer disposed on the light emitting device, a high refractive index layer disposed on the first layer and overlapping the light emitting device, and the first layer, and it may include a low refractive index layer disposed on the first layer and having a lower refractive index than the high refractive index layer, a side surface of the high refractive index layer and a side surface of the low refractive index layer are in contact with each other to form an inclined surface, and an angle of the inclined plane may be in a range of about 45 degrees to about 80 degrees.

The refractive index of the high refractive index layer may be about 1.6 or more.

The refractive index of the low refractive index layer may be about 1.5 or less.

The refractive index of the first layer may be about 1.6 or more.

A cross-section of the high refractive index layer perpendicular to an upper surface of the substrate may have an inverted trapezoidal shape.

An interface between the high refractive index layer and the low refractive index layer may not overlap the light emitting device in a direction perpendicular to an upper surface of the substrate.

The low refractive index layer may not overlap the light emitting device in a direction perpendicular to an upper surface of the substrate.

It may further include a second layer disposed between the first layer and the light emitting device, wherein the second layer may have a refractive index of about 1.6 or less and the second layer may have a thickness of about 1 μm or less.

A portion of the high refractive index layer may be disposed on the low refractive index layer.

The high refractive index layer may have a flat upper surface.

The display devices may further include a second layer disposed on the high refractive index layer, and an upper surface of the high refractive index layer may have a step portion in an area overlapping the light emitting device, and the second layer may fill the step portion.

A display device according to another embodiment may include a substrate, a light emitting device disposed on the substrate, a first layer disposed on the light emitting device, and a low refractive index layer disposed on the first layer. The first layer may be disposed on the substrate, and a protrusion portion may protrude in a direction away from the substrate, and a cross-section of the high refractive index layer perpendicular to an upper surface of the substrate may have a trapezoidal shape.

An angle formed between the side surface of the protrusion portion and the upper surface of the substrate may be in a range of about 45 degrees to about 80 degrees.

The refractive index of the first layer may be about 1.6 or more, and the refractive index of the low refractive index layer may be about 1.5 or less.

The low refractive index layer may be disposed to overlap the protrusion portion of the first layer.

The display devices may further include a second layer disposed on the high refractive index layer, and the upper surface of the low refractive index layer overlapping the protrusion portion may include a step portion, and the second layer may fill the step portion.

An interface between the side of the low refractive index layer and the second layer may form an inclined surface.

The protrusion portion of the first layer may overlap the light emitting device.

A display device according to another embodiment may include a substrate, a light emitting device disposed on the substrate, a first layer disposed on the light emitting device, a second layer disposed on the first layer, and a metal layer disposed on an inclined surface disposed inside the second layer, and an angle of the inclined surface may be in a range of about 45 degrees to about 80 degrees.

The inclined surface may not overlap the light emitting device.

According to embodiments, a method of manufacturing the display device and a display device with improved luminous efficiency are provided.

### BRIEF DESCRIPTION OF THE DRAWINGS

FIG. 1 is a schematic cross-sectional view of a display device according to an embodiment.

FIG. 2 shows the intensity of radiation distribution inside the first layer according to the refractive index of the first layer.

FIG. 3 shows an optical path of a display device according to an embodiment.

FIG. 4 shows radiation distribution of a display device, which includes a high refractive index layer and a low refractive index layer structure, according to embodiments, and radiation distribution of a display device, which does not include the high refractive index layer and the low refractive index layer structure, according to comparative examples.

FIG. 5 is a schematic cross-sectional view of the display device of FIG. 1 according to another embodiment.

FIG. 6 is a graph showing the transmittance according to the thickness of the third layer.

FIG. 7 is a schematic cross-sectional view of the display device of FIG. 1 according to another embodiment.

FIG. 8 is a schematic cross-sectional view of the display device of FIG. 7 according to another embodiment.

FIG. 9 is a schematic cross-sectional view of the display device of FIG. 1 according to another embodiment.

FIG. 10 is a schematic cross-sectional view of the display device of FIG. 1 according to another embodiment.

FIGS. 11, 12, 13, 14, 15, and 16 illustrate a method of manufacturing a display device according to an embodiment.

FIG. 17 and FIG. 18 illustrate a method of manufacturing a display device according to another embodiment.

FIG. 19 and FIG. 20 illustrate a method of manufacturing a display device according to another embodiment.

FIG. 21 illustrates a method of manufacturing a display device according to another embodiment.

FIGS. 22, 23, 24, 25, and 26 illustrate a method of manufacturing a display device according to another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Then, the display device according to an embodiment will be described below with reference to the drawings.

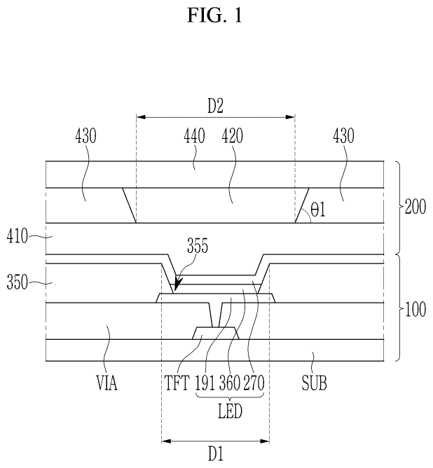

FIG. 1 is a schematic cross-sectional view of a display device according to an embodiment.

Referring to FIG. 1, the display device according to an embodiment may include a first area 100 and a second area 200. The first area 100 may be an area where the light emitting device LED is disposed and emits light, and the second area 200 may be an area where light emitted from the light emitting device LED is transmitted. This embodiment may be capable of improving the emission of light emitted from the first area 100 by adjusting the refractive index and shape of the second area 200.

The first area 100 will be described below. The first area 100 may include a substrate SUB and a transistor TFT disposed on the substrate SUB. An insulating film VIA may be disposed on the transistor TFT, and the first electrode 191 may be disposed on the insulating film.

A partition wall 350 may be positioned on the first electrode 191, and the partition wall 350 may include an opening 355 that overlaps the first electrode 191. A light emitting layer 360 may be disposed in (or within) the opening 355. The second electrode 270 may be positioned on the partition wall 350 and the light emitting layer 360. The first electrode 191, the light emitting layer 360, and the second electrode 270 may form a light emitting device LED. The portion where the first electrode 191, the light emitting layer 360, and the second electrode 270 overlap in the first area 100 may be a light emitting area where light emission actually occurs.

The second area 200 may include a first layer 410 disposed on the light emitting device LED, a high refractive index layer 420, a low refractive index layer 430, and a high refractive index layer 420 disposed on the first layer 410 and a second layer 440 disposed on the low refractive index layer 430.

The refractive index of the first layer 410 may be about 1.6 or more. For example, the refractive index of the first layer 410 may be about 1.8. The thickness of the first layer 410 may be about 5 μm to about 15 μm, but embodiments are not limited thereto. The first layer 410 may include organic or inorganic materials. The first layer 410 may be multi-layered, and may be a layer in which organic and inorganic layers are alternately stacked. In case that the first layer 410 is multilayered, the refractive index of each layer may be about 1.6 or more.

The first layer 410 may be disposed on the light emitting device LED and may be disposed in contact with the light emitting device LED. The first layer 410 may protect the light emitting device LED and may prevent moisture and humidity from penetrating into the light emitting device LED. However, this is an example, and the first layer 410 may be positioned to overlap the light emitting device LED without directly contacting it.

The first layer 410 may include, but embodiments are not limited thereto, one or more selected from the group consisting of SiNₓ, AlOₓ, TiOₓ, and SiOₓN_{y}. The x may be in a range of 1 to 4. The first layer 410 may be a single layer structure or a multilayer structure that satisfies the refractive index requirement of about 1.6 or more.

The high refractive index layer 420 may be positioned to overlap the light emitting device LED. The refractive index of the high refractive index layer 420 may be about 1.6 or more, for example, about 1.8 or more.

The high refractive index layer 420 may include a ceramic material such as TiO₂, ZrO₂, or ZnO, or a polymer material including such a ceramic material, and may be formed by a solution process, a chemical vapor deposition (CVD) process, a sputtering process, etc.

In another example, the high refractive index layer 420 may include an inorganic material such as SiOₓN_{y}, SiNₓ, AlOₓ, or ZnS, and may be formed by a thermal evaporation process, a chemical vapor deposition (CVD) process, a sputtering process, etc.

In another example, the high refractive index layer 420 may include a single molecule organic material, and may be formed by a thermal evaporation process, a solution process, etc.

In another example, the high refractive index layer 420 may include a high refractive index polymer material such as polyethylene naphthalate (PEN) or polyimide (PI), and may be formed by a solution process, a chemical vapor deposition (CVD) process, etc.

The high refractive index layer 420 may include a composite material including one or more of the above materials.

A low refractive index layer 430 may be disposed on sides (e.g., opposite sides) of the high refractive index layer 420. The refractive index of the low refractive index layer 430 may be lower than the refractive index of the high refractive index layer 420. For example, the refractive index of the low refractive index layer 430 may be about 1.5 or less.

The low refractive index layer 430 may be made of acrylic resin, methacrylic resin, polyisoprene, vinyl resin, epoxy resin, urethane resin, cellulose resin, siloxane resin, polyimide resin, polyamide resin, and perylene resin, and it may include polymer materials, and may be formed by a thermal evaporation process or solution processes.

In another example, the low refractive index layer 430 may include an inorganic material such as SiO₂, MgF₂, or LiF, and may be formed by a thermal evaporation process, a chemical vapor deposition (CVD) process, a sputtering process, etc.

The low refractive index layer 430 may include a composite material including one or more of the above materials.

As shown in FIG. 1, the low refractive index layer 430 may be disposed on sides (e.g., opposite sides) of the high refractive index layer 420. The high refractive index layer 420 may have a cross-section of an inverted trapezoidal structure in which the width of the lower surface closest to the substrate SUB is narrower than the width of the upper surface farther from the substrate SUB. For example, the side surface of the high refractive index layer 420 may form an inclined surface. For example, the first angle θ1 formed between the side surface of the high refractive index layer 420 and the top surface (or upper surface) of the first layer 410 may be about 45 degrees to about 80 degrees. As will be described later, in case that the first angle θ1 is less than about 45 degrees, it may be difficult for light emitted laterally from the light emitting device LED to reach the interface between the high refractive index layer 420 and the low refractive index layer 430. Additionally, in case that the first angle θ1 is greater than about 80 degrees, light totally reflected at the interface between the high refractive index layer 420 and the low refractive index layer 430 may not be emitted to the front.

The high refractive index layer 420 and the low refractive index layer 430 may be disposed on the same layer (e.g., the first layer 410), and as shown in FIG. 1, the upper surfaces of the high refractive index layer 420 and the low refractive index layer 430 may be disposed at the same level (or may be coplanar with each other). However, this is an example, and a portion of the high refractive index layer 420 may be disposed on the low refractive index layer 430. The thickness of the high refractive index layer 420 and the low refractive index layer 430 may be about 3 μm to about 7 μm, respectively, but embodiments are not limited thereto.

The width D2 of the high refractive index layer 420 may be wider than the width of the light emitting area D1. For example, as shown in FIG. 1, the interface between the high refractive index layer 420 and the low refractive index layer 430 may not overlap in the direction perpendicular to the light emitting device LED and the substrate. Therefore, as will be described later, light efficiency may be increased through total reflection of light emitted from the light emitting device LED to the side without interfering with the emission of light emitted from the front.

The second layer 440 may be positioned on the high refractive index layer 420 and the low refractive index layer 430. The second layer 440 may cover the upper surfaces of the high refractive index layer 420 and the low refractive index layer 430. The refractive index of the second layer 440 may be about 1.5, but embodiments are not limited thereto. The thickness of the second layer 440 may be about 20 μm to about 30 μm. The second layer 440 may flatten the upper surfaces of the high refractive index layer 420 and the low refractive index layer 430.

According to the embodiment, the refractive index of the first layer 410 and the high refractive index layer 420 may be the same as each other, but this is an example and embodiments are not limited thereto.

In the display device according to an embodiment, the high refractive index layer 420 may be disposed to overlap the light emitting element LED, and the low refractive index layer 430 may be disposed on sides (e.g., opposite sides) of the high refractive index layer 420. The interface between the high refractive index layer 420 and the low refractive index layer 430 may form an inclined surface, and light emitted from the side of the light emitting device LED may be reflected (e.g., totally reflected) by the inclined surface, thereby increasing luminous efficiency. The effects are described below.

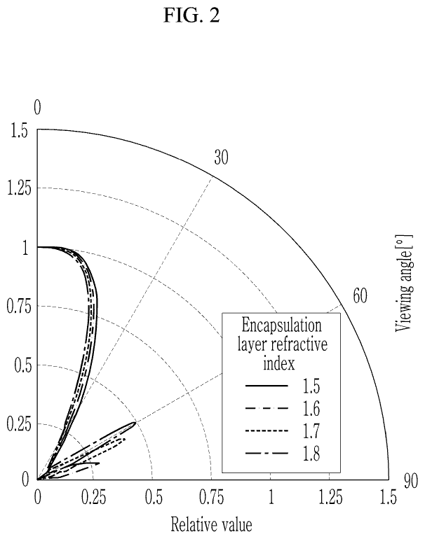

FIG. 2 shows the intensity of radiation distribution inside the first layer 410 according to the refractive index of the first layer 410. As shown in FIG. 2, it was confirmed that a significant portion of light emitted from the light emitting device LED in a 60-degree direction exists. However, there was a problem in that the light emitted in this 60-degree direction could not escape (or emit) from the display device, thereby reducing the efficiency of the display device.

However, the display device according to an embodiment may include a high refractive index layer 420 having a wider width than the light emitting element LED and a low refractive index layer 430 disposed on sides (e.g., opposite sides) of the high refractive index layer 420, and at the interface of the high refractive index layer 420 and the low refractive index layer 430, total reflection may be induced to allow light emitted from the light emitting device LED in a 60-degree direction to escape (or emit) out of the display device, thereby improving efficiency.

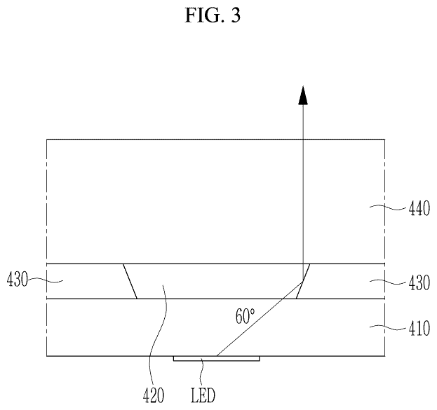

FIG. 3 shows the second area 200 and the light emitting element LED of the display device according to an embodiment, and shows the light path. As shown in FIG. 3, light emitted from the light emitting device in a direction of 60 degrees may be reflected (e.g., totally reflected) at the interface between the high refractive index layer 420 and the low refractive index layer 430 and may be emitted to the front. Therefore, the luminous efficiency of the display device may be improved.

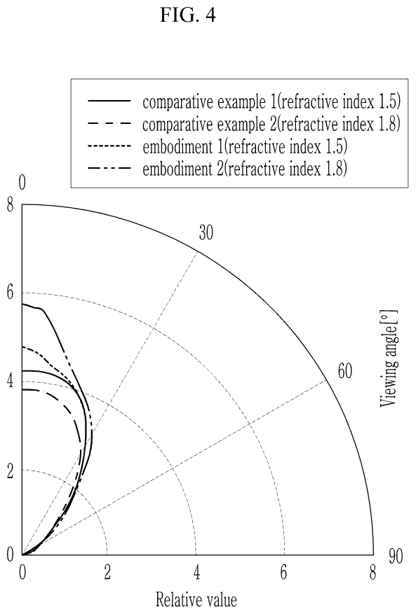

FIG. 4 shows radiation distribution of a display device (e.g., Embodiment 1 and Embodiment 2) including a high refractive index layer 420 and a low refractive index layer 430 according to an embodiment, and a high refractive index layer 420 according to an embodiment, which shows the radiation distribution outside the display device for a display device (e.g., Comparative Examples 1 and 2) that does not include the low refractive index layer 430.

Embodiment 1 and Comparative Example 1 are cases where the refractive index of the first layer is about 1.5, and Embodiment 2 and Comparative Example 2 are cases where the refractive index of the first layer is about 1.8. In case of comparing Comparative Example 1 and Embodiment 1 with reference to FIG. 4, it was confirmed that Example 1 had a further increase in external radiation intensity. In case of comparing Comparative Embodiment 2 with Embodiment 2, it was confirmed that Embodiment 2 had a further increase in external radiation intensity. For example, as the display device including the high refractive index layer 420 and the low refractive index layer 430 according to the embodiment does not include the high refractive index layer 420 and the low refractive index layer 430, it was confirmed that the luminous efficiency was improved compared to the embodiment.

Table 1 compares the relative efficiencies of Comparative Example 2, Embodiment 1, and Embodiment 2 in case that the efficiency of Comparative Example 1 is set to about 100%. As shown in Table 1, it was confirmed that the efficiency of Embodiments 1 and 2 was improved compared to the efficiency of Comparative Examples 1 and 2.

TABLE 1

| | Efficiency |
|---|---|
| Comparative Example 1 (refractive index = 1.5) | 100% |
| Comparative Example 2 (refractive index = 1.8) | 91.7% |
| Embodiment 1 (refractive index = 1.5) | 112.6% |
| Embodiment 2 (refractive index = 1.8) | 135.3% |

Table 2 shows the relative efficiency of Embodiment 1 in case that the efficiency of Comparative Example 1 is set to about 100%. Referring to Table 2, it was confirmed that the efficiency of Embodiment 1 increased by about 12.6% compared to Comparative Example 1.

TABLE 2

| | Comparative Example 1 | Embodiment 1 |
|---|---|---|
| Efficiency | 100% | 112.6% |

Table 3 shows the relative efficiency of Embodiment 2 in case that the efficiency of Comparative Example 2 is set to about 100%. Referring to Table 3, it was confirmed that the efficiency of Embodiment 2 increased by about 48.6% compared to Comparative Example 2.

TABLE 3

| | Comparative Example 2 | Embodiment 2 |
|---|---|---|
| Efficiency | 100% | 148.6% |

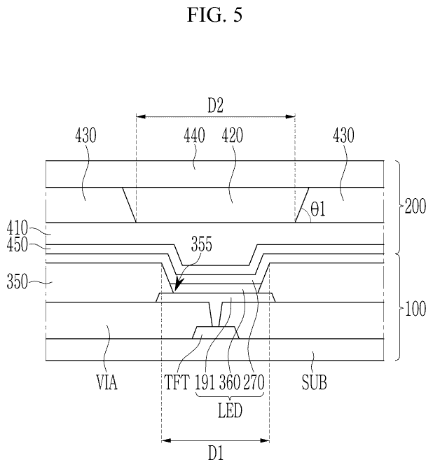

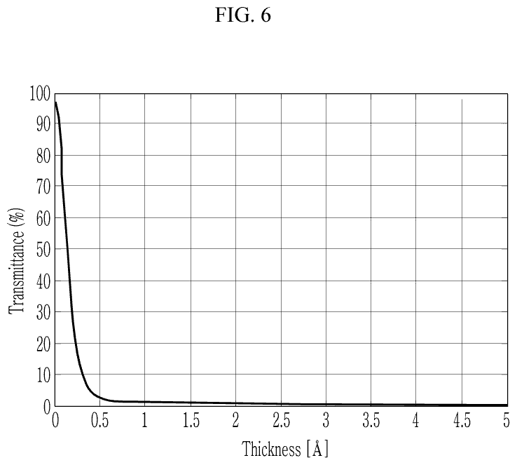

For example, other embodiments will be described below with reference to the drawings. FIG. 5 is a schematic cross-sectional view of the display device of FIG. 1 according to another embodiment. The display device according to the embodiment of FIG. 5 is the same as the embodiment of FIG. 1 except that it further includes a third layer 450 disposed between the light emitting device LED and the first layer 410. Detailed descriptions of the same components are omitted for descriptive convenience. The third layer 450 may have a refractive index of less than about 1.6, and the thickness of the third layer 450 may be about 1 μm or less. In order for light emitted from the light emitting device LED of the first area 100 to be incident on the second area 200, the refractive index of the layer disposed on the optical path must be about 1.6 or more. However, as shown in FIG. 5, in case that the layer has a refractive index of less than about 1.6, in case that the thickness is about 1 μm or less, it may transmit light and may be applied to the display device according to the embodiment. FIG. 6 is a graph showing the transmittance according to the thickness of the third layer 450. As shown in FIG. 6, it was confirmed that light could be transmitted in case that the thickness of the third layer 450 was about 1 μm or less.

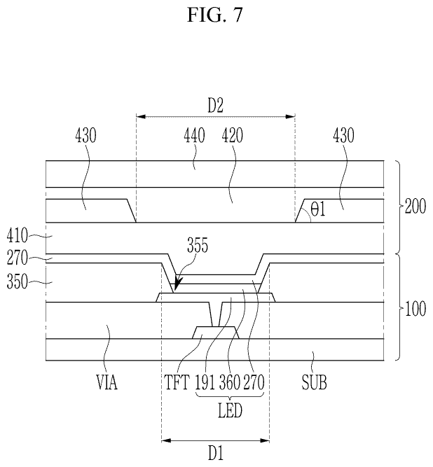

FIG. 7 is a schematic cross-sectional view of the display device of FIG. 1 according to another embodiment. Referring to FIG. 7, the display device according to an embodiment is the same as FIG. 1 except that a portion of the high refractive index layer 420 overlaps the low refractive index layer 430 in a direction perpendicular to the substrate SUB. Detailed descriptions of the same components are omitted for descriptive convenience. As shown in FIG. 7, although a portion of the high refractive index layer 420 overlaps the low refractive index layer 430 in a direction perpendicular to the substrate SUB, since the interface between the high refractive index layer 420 and the low refractive index layer 430 forms an inclined surface, total reflection may occur on the inclined surface, and luminous efficiency may be improved.

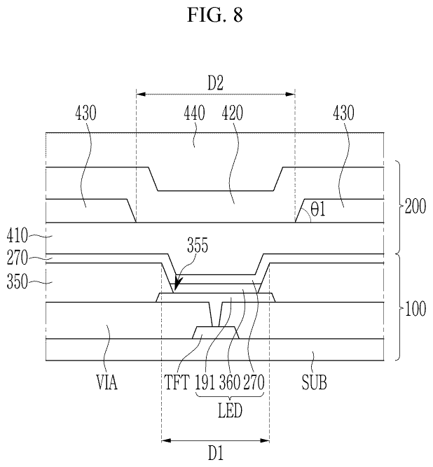

FIG. 8 is a schematic cross-sectional view of the display device of FIG. 7 according to another embodiment. Referring to FIG. 8, the display device according to an embodiment is the same as the embodiment of FIG. 7 except for the shape of the high refractive index layer 420 and the shape of the second layer 440. Detailed descriptions of the same components are omitted for descriptive convenience. Referring to FIG. 8, the high refractive index layer 420 according to an embodiment may have an overall uniform thickness. Accordingly, a step portion may be formed on the upper surface of the high refractive index layer 420, and the second layer 440 may fill the step portion. For example, since the interface between the high refractive index layer 420 and the low refractive index layer 430 forms an inclined surface, total reflection occurs on the inclined surface and luminous efficiency may be improved.

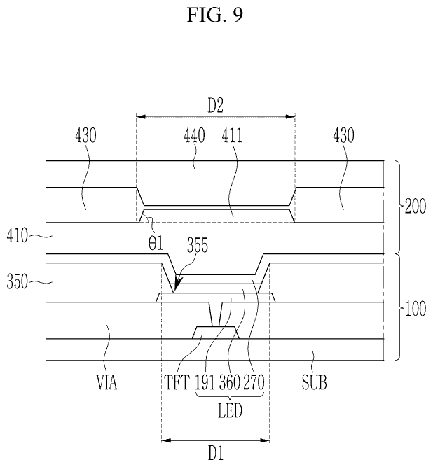

FIG. 9 is a schematic cross-sectional view of the display device of FIG. 1 according to another embodiment. Referring to FIG. 9, the display device according to an embodiment may not include the high refractive index layer 420, but may include a protrusion portion 411 in which a portion of the first layer 410 protrudes and has a trapezoidal cross-section. For example, total reflection of light emitted from the light emitting device may occur at the interface between the protrusion portion 411 of the first layer 410 and the low refractive index layer 430. The angle θ1 of the inclined plane formed by the side surface of the protrusion portion 411 of the first layer 410 and the side surface of the low refractive index layer 430 may be about 45 degrees to about 80 degrees.

As shown in FIG. 9, the protrusion portion 411 of the first layer 410 may overlap the low refractive index layer 430 in a direction perpendicular to the substrate SUB. Since the low refractive index layer 430 is located on the protrusion portion 411 of the first layer 410, the optical path of the emitted light may be adjusted.

As shown in FIG. 9, a step portion may be formed on the upper surface of the low refractive index layer 430, and the second layer 440 may fill the step portion.

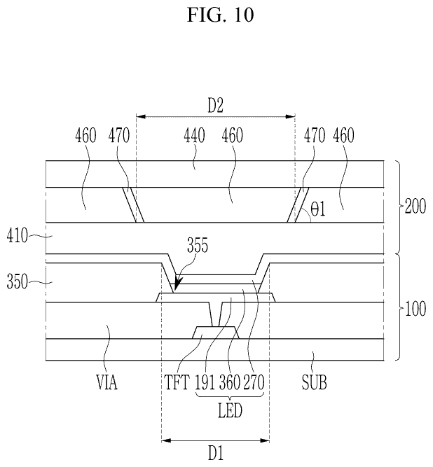

FIG. 10 is a schematic cross-sectional view of the display device of FIG. 1 according to another embodiment. In the case of the embodiment of FIG. 10, instead of the low refractive index layer 430 and the high refractive index layer 420, it may further include a fourth layer 460 and a metal layer 470 disposed on an inclined surface inside the fourth layer 460. The refractive index of the fourth layer 460 may be equal to or greater than the refractive index of the first layer 410. Although a metal layer 470 is disposed instead of the interface of the low refractive index layer 430 and the high refractive index layer 420, it may improve the light emitting efficiency by reflecting (e.g., totally reflecting) the light emitted from the side of the light emitting device LED and emitting the light to the front.

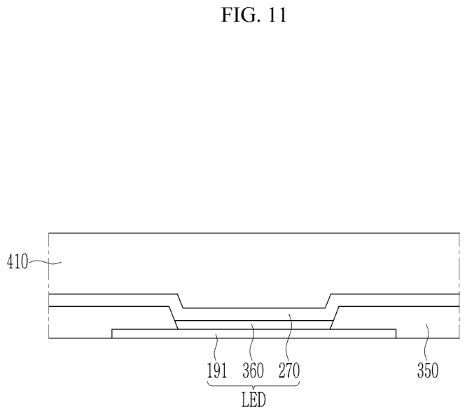

For example, the manufacturing method of the display device according to an embodiment will be described in detail below with reference to the drawings. FIGS. 11, 12, 13, 14, 15, and 16 illustrate a method of manufacturing a display device according to an embodiment. In FIGS. 11 to 16, only some of the components of the first area 100 are shown for convenience of explanation. For example, the configuration of the light emitting element LED including the first electrode 191, the light emitting layer 360, and the second electrode 270, and the partition wall 350, is shown. Hereinafter, the second area 200 will be described focusing on the composition.

Referring to FIG. 11, the first layer 410 may be formed on the light emitting device LED.

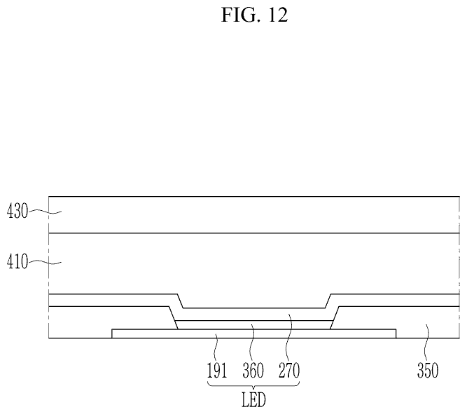

Referring to FIG. 12, a low refractive index layer 430 may be formed on the entire surface of the first layer 410.

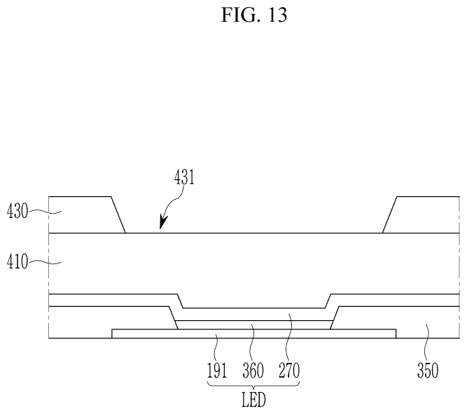

Referring to FIG. 13, the low refractive index layer 430 may be patterned to form an opening 431.

For example, the width of the opening 431 may be wider than the width of the light emitting device LED.

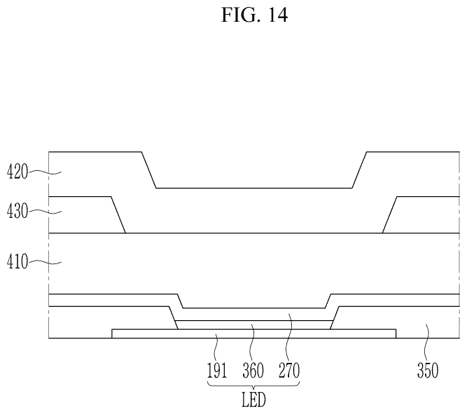

Referring to FIG. 14, a high refractive index layer 420 may be formed in the low refractive index layer 430 and the opening 431. The high refractive index layer 420 may be formed to a uniform thickness.

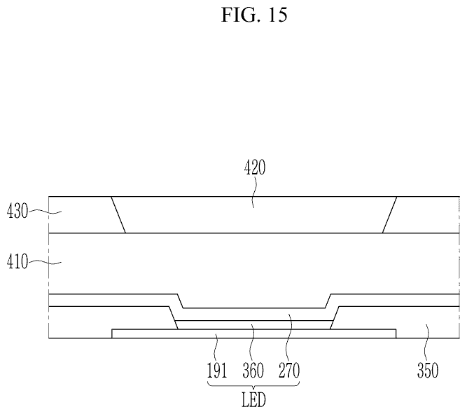

For example, the high refractive index layer 420 may be planarized, with reference to FIG. 15.

In this step, the high refractive index layer 420 disposed on the low refractive index layer 430 may be removed, as shown in FIG. 15.

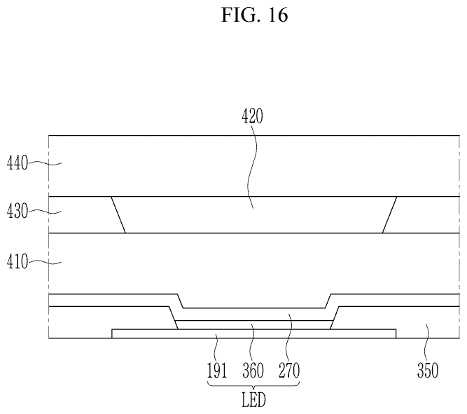

Referring to FIG. 16, a second layer 440 may be formed on the low refractive index layer 430 and the high refractive index layer 420.

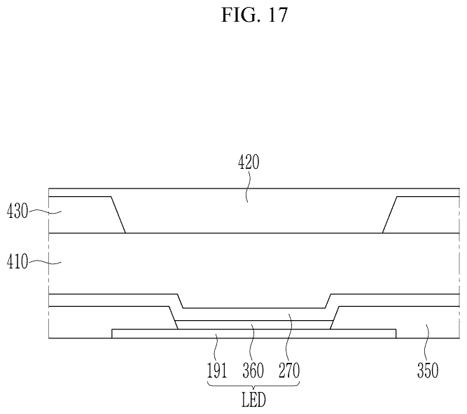

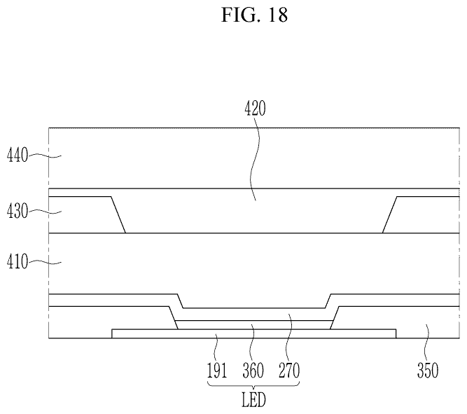

For example, a manufacturing method according to another embodiment will be described below. The manufacturing method according to an embodiment is the same as the processes of FIGS. 11 to 14 described above, and the subsequent processes will be described. FIG. 17 and FIG. 18 illustrate a method of manufacturing a display device according to another embodiment.

Referring to FIG. 17, the high refractive index layer 420 may be planarized. At this stage, as shown in FIG. 17, the high refractive index layer 420 disposed on the low refractive index layer 430 may not be completely removed and some may remain.

Referring to FIG. 18, the second layer 440 may be formed on the low refractive index layer 430 and the high refractive index layer 420. The display device according to the embodiment of FIG. 6 may be manufactured by this manufacturing method.

In another embodiment, the planarization process may be omitted. Below, a manufacturing method according to another embodiment will be described. The processes of FIGS. 11 to 13 described above are the same, and the subsequent processes will be described.

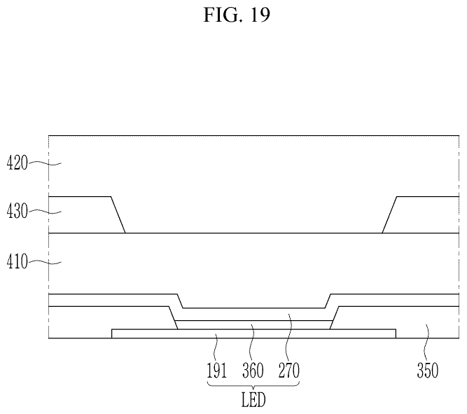

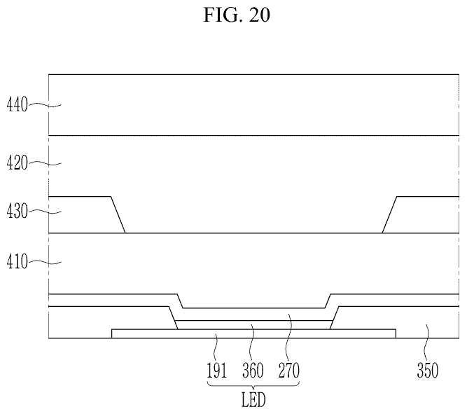

FIG. 19 and FIG. 20 illustrate a method of manufacturing a display device according to another embodiment. Referring to FIG. 19, a high refractive index layer 420 may be formed on the low refractive index layer 430. For example, the high refractive index layer 420 may have flowability and may be formed to have a flat top surface (or flat upper surface). Referring to FIG. 20, the second layer 440 may be formed on the low refractive index layer 430 and the high refractive index layer 420, and therefore, as shown in FIG. 20, the upper surface of the high refractive index layer 420 may be flat and a separate flattening process may not be required. The display device according to the embodiment of FIG. 6 may be manufactured by this manufacturing method.

A manufacturing method according to another embodiment will be described below. The manufacturing method according to an embodiment is the same as the processes of FIGS. 11 to 14 described above, and the subsequent processes will be described. The manufacturing method according to an embodiment may also not include a separate planarization process.

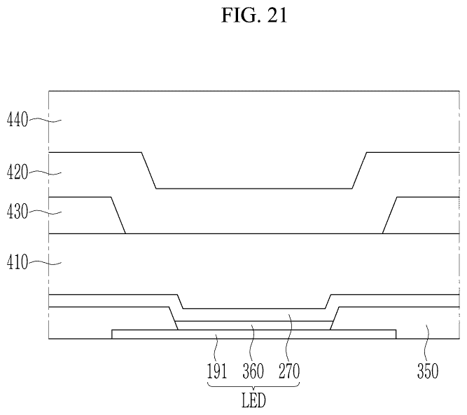

Referring to FIG. 21, the second layer 440 may be formed on the high refractive index layer 420 with a step portion on the upper surface without a separate planarization process. The second layer 440 may have a flat top surface (or flat upper surface) by filling the step portion of the top surface (or upper surface) of the high refractive index layer 420. The display device according to the embodiment of FIG. 7 may be manufactured by this manufacturing method.

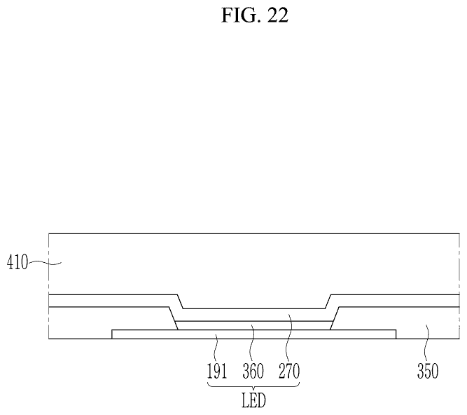

FIGS. 22, 23, 24, 25, and 26 illustrate a method of manufacturing a display device according to another embodiment.

Referring to FIG. 22, the first layer 410 may be formed on the light emitting device LED.

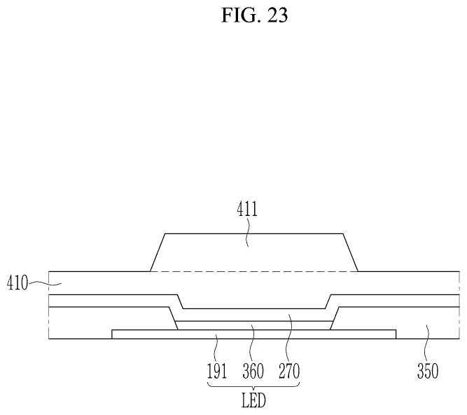

Referring to FIG. 23, the first layer 410 may be patterned to form the protrusion portion 411 of the first layer 410. For example, the cross-section of the protrusion portion 411 may have a trapezoidal shape.

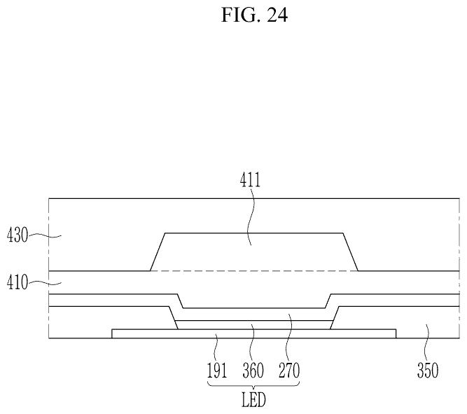

Referring to FIG. 24, a low refractive index layer 430 may be formed on the entire surface above the first layer 410.

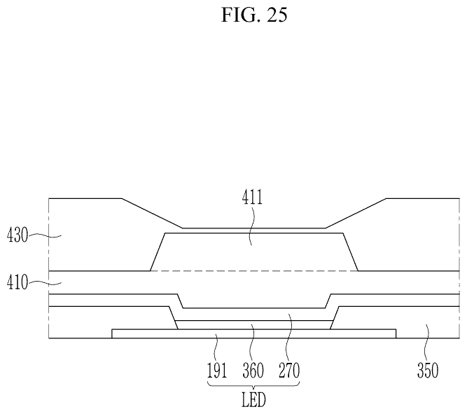

Referring to FIG. 25, the low refractive index layer 430 may be patterned to form an opening. For example, the low refractive index layer 430 may remain on the upper surface of the protrusion portion 411 of the first layer 410.

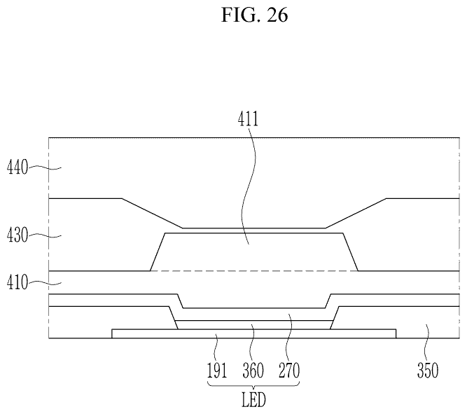

Referring to FIG. 26, a second layer 440 may be formed. The second layer 440 may have a flat top surface (or flat upper surface) with filling the step portion of the top surface (or upper surface) of the low refractive index layer 430.

The display device according to the embodiment of FIG. 8 may be manufactured by this manufacturing method. However, this manufacturing method is an example, and embodiments are not limited thereto.

As described above, the display device and its manufacturing method according to an embodiment may include a high refractive index layer 420 having a wider width than that of the light emitting element LED and a low refractive index layer 430 disposed on sides (e.g., opposite sides) of the high refractive index layer 420. For example, total reflection may be induced at the interface between the high refractive index layer 420 and the low refractive index layer 430, allowing light emitted from the light emitting layer LED in a diagonal direction to escape (or emit) out of the display device, thereby improving light output efficiency.

Although the embodiments of the invention have been described in detail above, the scope of the invention is not limited thereto, and various modifications and improvements made by those skilled in the art using the basic concepts of the invention defined in the following claims are also possible.

What is claimed is:

1. A display device comprising:
a substrate;
a light emitting device disposed on the substrate;
a first layer disposed on the light emitting device;
a high refractive index layer disposed on the first layer and overlapping the light emitting device; and
a low refractive index layer disposed on the first layer and having a lower refractive index than the high refractive index layer, wherein
a side surface of the high refractive index layer and a side surface of the low refractive index layer are in contact with each other to form an inclined surface, and
an angle of the inclined surface is in a range of about 45 degrees to about 80 degrees.

2. The display device of claim 1, wherein
the high refractive index layer has a refractive index of about 1.6 or more.

3. The display device of claim 1, wherein
the low refractive index layer has a refractive index of about 1.5 or less.

4. The display device of claim 1, wherein
the first layer has a refractive index of about 1.6 or more.

5. The display device of claim 1, wherein
a cross-section of the high refractive index layer perpendicular to an upper surface of the substrate has an inverted trapezoidal shape.

6. The display device of claim 1, wherein
an interface between the high refractive index layer and the low refractive index layer does not overlap the light emitting device in a direction perpendicular to an upper surface of the substrate.

7. The display device of claim 1, wherein
the low refractive index layer does not overlap the light emitting device in a direction perpendicular to an upper surface of the substrate.

8. The display device of claim 1, further comprising:
a second layer disposed between the first layer and the light emitting device, wherein
a refractive index of the second layer is about 1.6 or less, and
the second layer has a thickness of about 1 μm or less.

9. The display device of claim 1, wherein
a portion of the high refractive index layer is disposed on the low refractive index layer.

10. The display device of claim 1, wherein
the high refractive index layer has a flat upper surface.

11. The display device of claim 1, further comprising:
a second layer disposed on the high refractive index layer, wherein
an upper surface of the high refractive index layer has a step portion in an area overlapping the light emitting device, and
the second layer fills the step portion.

12. A display device comprising:
a substrate;
a light emitting device disposed on the substrate;
a first layer disposed on the light emitting device; and
a low refractive index layer disposed on the first layer, wherein
the first layer includes a protrusion portion protruding in a direction away from the substrate, and
a cross-section of the protrusion portion perpendicular to the substrate has a trapezoidal shape.

13. The display device of claim 12, wherein
an angle formed between a side surface of the protrusion portion and an upper surface of the substrate is in a range of about 45 degrees to about 80 degrees.

14. The display device of claim 12, wherein
a refractive index of the first layer is about 1.6 or more, and
the low refractive index layer has a refractive index of about 1.5 or less.

15. The display device of claim 12, wherein
the low refractive index layer overlaps the protrusion portion of the first layer.

16. The display device of claim 12, wherein
an upper surface of the low refractive index layer overlapping the protrusion portion includes a step portion, and
the display device further includes a second layer disposed on the low refractive index layer, and
the second layer fills the step portion.

17. The display device of claim 16, wherein
an interface between a side of the low refractive index layer and the second layer forms an inclined surface.

18. The display device of claim 12, wherein
the protrusion portion of the first layer is positioned to overlap the light emitting device.

19. A display device comprising:
a substrate;
a light emitting device disposed on the substrate;
a first layer disposed on the light emitting device;
a second layer disposed above the first layer; and
a metal layer disposed on an inclined surface inside the second layer,
wherein an angle of the inclined surface is in a range of about 45 degrees to about 80 degrees.

20. The display device of claim 19, wherein
the inclined surface does not overlap the light emitting device.
